(19) United States
(12) Patent Application Publication
(10) Pub. No.: US 2015/0160362 A1
(43) Pub. Date: Jun. 11, 2015

(54) Hand Tool Device

(71) Applicant: Robert Bosch GmbH, Stuttgart (DE)

(72) Inventors: Heiko Sgarz, Leonberg (DE); Jan-Michael Brosi, Leinfelden-Echterdingen (DE); Andrej Albrecht, Leinfelden-Echterdingen (DE)

(21) Appl. No.: 14/406,230

(22) PCT Filed: Apr. 15, 2013
(86) PCT No.: PCT/EP2013/057789

§ 371 Date: Dec. 8, 2014

(30) Foreign Application Priority Data
Jun. 14, 2012 (DE) 10 2012 210 009.1

(51) Int. Cl. G01V 3/10; G01R 1/18

(52) U.S. Cl. CPC G01V 3/10; G01R 1/18

(57) ABSTRACT

The disclosure relates to a hand tool device having at least one locating device which is provided in order to locate a low-frequency ac voltage in a workpiece and which has a first locating antenna and a second locating antenna. According to the disclosure the hand tool device has a shielding means for shielding a low-frequency locating signal, which shielding means is disposed between the first locating antenna and the second locating antenna.

### PRIOR ART

A hand tool device with at least one locating device which is provided in order to locate a low-frequency AC voltage in a workpiece and which has a first locating antenna and a second locating antenna has already been proposed.

### DISCLOSURE OF THE INVENTION

The invention is based on a hand tool device with at least one locating device which is provided in order to locate a low-frequency AC voltage in a workpiece and which has a first locating antenna and a second locating antenna.

It is proposed that the hand tool device has a shielding means intended for shielding a low-frequency locating signal and arranged between the first locating antenna and the second locating antenna. A “locating device” should be understood as meaning in particular a device which is provided in order to determine at least one piece of locational information about an object of measurement arranged in a workpiece. Preferably, the locating device has a computing unit, which is provided in order to determine at least one direction and/or a distance of the object of measurement in relation to the locating device. With preference, the locating device has an outputting means, by way of which the locating device outputs the locational information to an operator. “Provided” should be understood as meaning in particular especially programmed, designed and/or equipped. A “low-frequency AC voltage” should be understood as meaning in particular a voltage with a frequency lower than 100 kHz, advantageously lower than 10 kHz, particularly advantageously lower than 1 kHz. Preferably, the locating device is provided in order to locate a system voltage at 50 Hz and/or 60 Hz. The expression “in a workpiece” should be understood as meaning in particular that the locating device is provided in order to locate the object of measurement arranged within and/or concealed behind the workpiece. Preferably, the locating device is provided in order to receive a locating signal that has penetrated the workpiece. “Locate” should be understood as meaning in particular a determination of at least one item of locational information of an object of measurement arranged remotely and concealed. A “locating antenna” should be understood as meaning in particular a means which is provided in order to convert an electrically, magnetically and/or electromagnetically transmitted locating signal into a signal transmitted by an electrical conductor. A “shielding means” should be understood as meaning in particular a means which is provided in order to attenuate a low-frequency locating signal acting from one direction on the locating antenna by more than 6 dB, advantageously by more than 10 dB, particularly advantageously by more than 20 dB. In particular, the shielding means influences a main locating direction of the locating antennas. Preferably, the shielding means is formed as an electrically conducting layer. Alternatively or in addition, the shielding means could comprise a conducting grid, conducting strips, conducting subareas and/or other conducting elements that appear appropriate to a person skilled in the art. With preference, the shielding means is formed as a metal sheet and/or advantageously as a coating of an insulator, for example as a metallized plastic part or as a printed circuit board. For example, the shielding means could comprise copper, iron, ferrite and/or mu-metal. Preferably, the shielding means has a fixed electric potential, for example it could be connected in an electrically conducting manner to a ground of the locating device. Alternatively, it could be electrically insulated from the locating device. A “low-frequency locating signal” should be understood as meaning in particular a signal with a frequency of less than 1 kHz. The term “between” should be understood in this connection as meaning in particular that the shielding means lies on at least one straight line that intersects one of the locating antennas respectively on two opposite sides of the shielding means. Preferably, the shielding means lies between each point of the first locating antennas and, extending from the point, at least 50%, advantageously 75%, particularly advantageously 90%, of a surface area of the second locating antenna. The way in which the hand tool device is configured according to the invention makes it easy in terms of structural design to achieve different alignments of main locating directions of the locating antennas.

As a result, a particularly advantageous locational determination of the low-frequency AC voltage can be achieved.

In a further configuration it is proposed that the locating antennas are arranged symmetrically in relation to the shielding means, whereby a particularly easy determination of the locational information is possible with a computing unit. “Symmetrically arranged” should be understood as meaning in particular that midpoints of the locating antennas are arranged regularly in relation to an area of symmetry passing through a midpoint of the shielding means.

Furthermore, it is proposed that the first and/or the second locating antenna is formed by a conducting layer, whereby particularly low-cost production is possible. Furthermore, the locating antennas can be placed in a particularly space-saving manner. A “conducting layer” should be understood as meaning in particular a conducting region of which the thickness is less than 10% of a height and a width of the region. Preferably, the locating antennas are respectively formed as a metal sheet and/or advantageously as a coating of an insulator, for example as a metallized plastic part or as a printed circuit board.

It is further proposed that the hand tool device comprises a second locating device with at least one locating antenna, the shielding means at least substantially enclosing the locating antenna of the second locating device, whereby a further locating direction can be located easily in terms of structural design. The expression “enclose at least substantially on at least one plane” should be understood as meaning in particular that rays emanating from the midpoint of the locating antenna that are arranged on the plane intersect the shielding means over an angular range of more than 180 degrees, advantageously more than 270 degrees. Particularly advantageously, the shielding means encloses the locating antenna of the third locating device by 360 degrees.

Moreover, it is proposed that the second locating device is provided in order to locate with a high-frequency locating signal, whereby voltage-free objects of measurement can be advantageously located. Preferably, the locating antenna of the second locating device is formed in the way described in the document DE 10 2008 041 651 A1. Alternatively or in addition, the locating antenna of the second locating device could be provided in order to locate an object of measurement inductively and/or capacitively. Furthermore, the second locating device could be provided in order to locate a low-frequency AC voltage.

A “high-frequency locating signal” should be understood as meaning in particular a locating signal with a frequency greater than 1 kHz, advantageously greater than 1 MHz. Preferably, the third locating device is provided in order to locate with an ultra wideband signal. An “ultra wideband signal” should be understood as meaning in particular a locating signal with a medium frequency in the frequency range from 250 MHz to 15 GHz and a frequency bandwidth of at least 500 MHz. Alternatively or in addition, the second locating device could be provided in order to locate with a smallband locating signal.

Furthermore, it is proposed that the first and the second locating antenna are arranged symmetrically in relation to the locating antenna of the second locating device, whereby a particularly easy determination of the locational information is possible with a computing unit.

In an advantageous form of the invention it is proposed that the first and the second locating antenna have a main extent that is aligned substantially parallel to a main locating direction of the locating antenna of the second locating device, whereby a particularly space-saving configuration of the hand tool device can be achieved. A “main plane of extent” should be understood as meaning in particular a plane with a maximum extent. “Substantially parallel” should be understood as meaning in particular that an extent of the main plane of extent deviates less than 20 degrees, preferably less than 10 degrees, from the main locating direction. A “main locating direction” should be understood as meaning in particular a direction in which the locating antenna has a maximum sensitivity. In the case of a locating antenna which is provided in order to emit maximum energy in different directions in different operating states, the “main locating direction” should be advantageously understood as meaning an average direction of the different directions.

Furthermore, it is proposed that the hand tool device has a functional opening, at least two of the locating antennas, in particular the locating antennas of the first locating device and of a second locating device, being arranged symmetrically in relation to the functional opening, whereby the workpiece can be comfortably machined and/or marked at a place at which a locating operation has been carried out. A “functional opening” should be understood as meaning in particular an opening in the hand tool device through which a functional means, for example a drill and/or a pin, can be guided to the workpiece, while a housing of an appliance comprising the hand tool device is placed with a locating side on the workpiece.

It is further proposed that the first locating device has a third locating antenna and a fourth locating antenna, the shielding means being arranged between the third locating antenna and the fourth locating antenna, whereby particularly accurate locating of the low-frequency AC voltage is possible.

Furthermore, the invention is based on a hand tool with a hand tool device. A “hand tool” should be understood as meaning in particular a tool that appears appropriate to a person skilled in the art, but advantageously a power drill, a hammer drill, a percussion hammer, a saw, a plane, a screwdriver, a milling machine, a grinder, an angle grinder, a garden implement, a multifunctional tool and/or particularly advantageously a construction site measuring instrument.

### DRAWING

Further advantages emerge from the following description of the drawing. In the drawing, four exemplary embodiments of the invention are represented. The drawing, the description and the claims contain numerous features in combination. A person skilled in the art will expediently also consider the features individually and put them together into appropriate further combinations.

In the drawing:

FIG. 1 shows a hand tool with a hand tool device according to the invention,

FIG. 2 shows four locating antennas of a first locating device, a locating antenna of a second locating device and a shielding means of the hand tool device from FIG. 1 in a perspective view,

FIG. 3 shows a schematic section of the hand tool device from FIG. 1,

FIG. 4 shows a schematic section of a second, alternative exemplary embodiment of the hand tool device from FIG. 1,

FIG. 5 shows a schematic section of a third, alternative exemplary embodiment of the hand tool device from FIG. 1 and

FIG. 6 shows a schematic section of a fourth, alternative exemplary embodiment of the hand tool device from FIG. 1.

### DESCRIPTION OF THE EXEMPLARY EMBODIMENTS

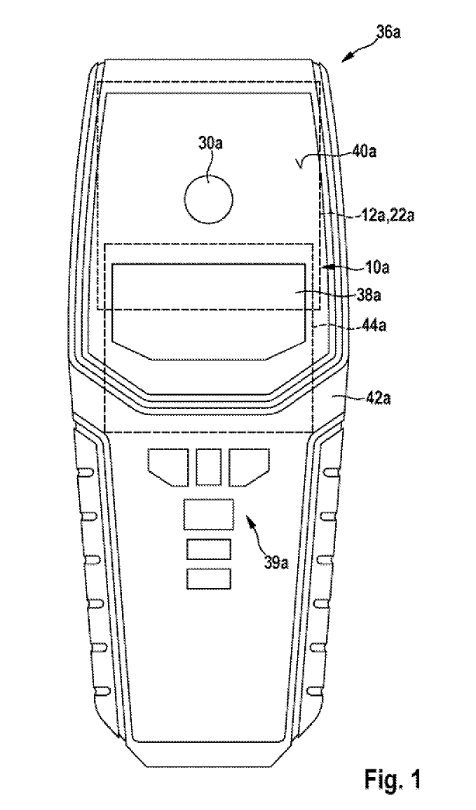

FIG. 1 shows a hand tool 36a, formed as a handheld locating appliance, with a hand tool device 10a according to the invention, a display unit 38a, an operator control unit 39a and a hand tool housing 42a.

The hand tool housing 42a encloses an interior space, in which the hand tool device 10a is arranged. The display unit 38a and the operator control unit 39a are arranged on a front side 40a of the hand tool housing 42a. The hand tool 36a is provided in order to be placed with a rear side 41a on a workpiece 14a in a locating operation. By means of the operator control unit 39a, the hand tool device 10a can be configured by an operator. The hand tool device 10a outputs locating results to the operator by way of the display unit 38a.

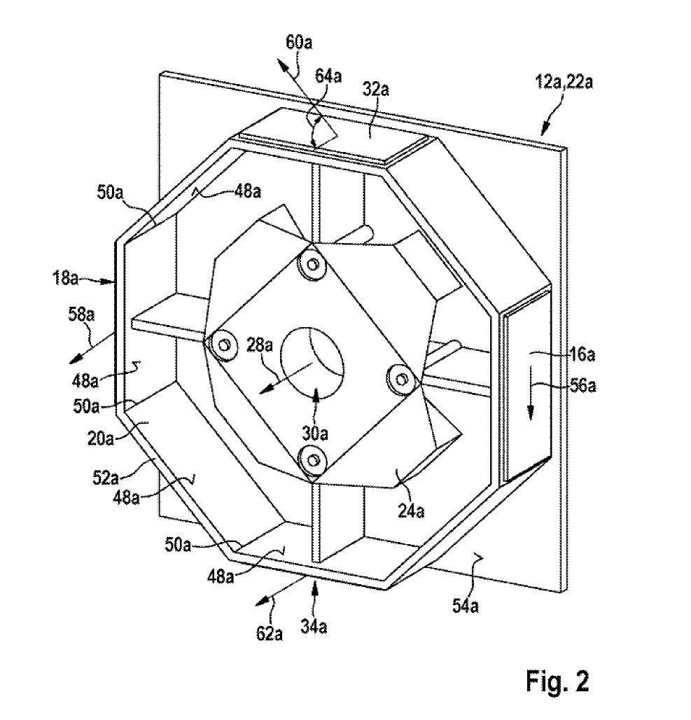

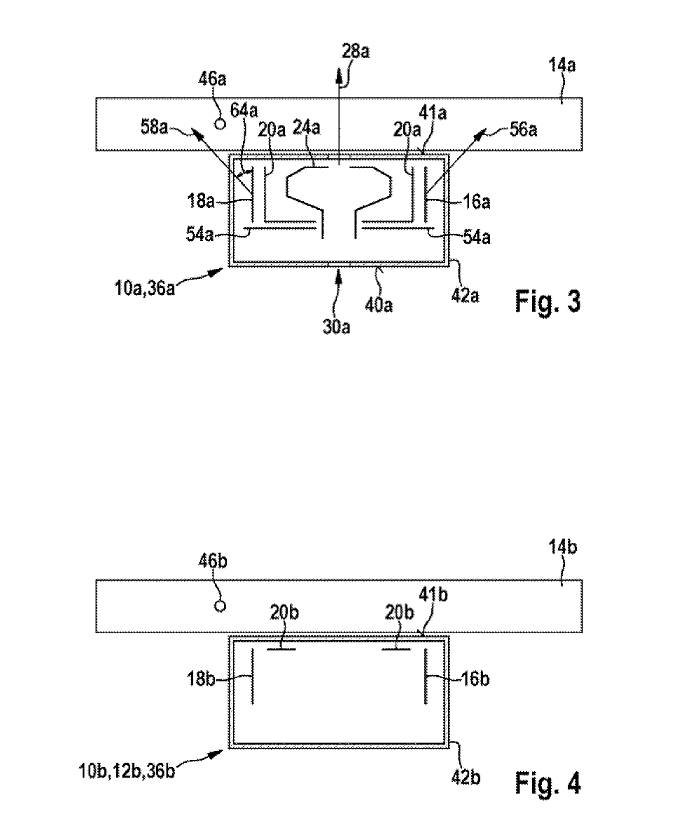

As FIGS. 2 and 3 show, the hand tool device 10a comprises a first locating device 12a with four locating antennas 16a, 18a, 32a, 34a, a shielding means 20a, a second locating device 22a with a locating antenna 24a and locating electronics 44a of the first and the second locating device 12a, 22a. The locating electronics 44a comprise, not shown any more specifically here, a computing unit and signal processing devices of the first and the second locating device 12a, 22a.

The signal processing devices process locating signals for the computing unit that come from the locating antennas 16a, 18a, 24a, 32a, 34a. The signal processing device of the first locating device 12a comprises a filter and an amplifier, which are provided in order to filter out and amplify a received low-frequency locating signal. The locating antennas 16a, 18a, 24a, 32a, 34a are galvanically connected to a printed circuit board of the signal processing device. Alternatively, the locating antennas 16a, 18a, 24a, 32a, 34a could be connected to a printed circuit board of the signal processing device by way of a capacitive coupling.

The signal processing device of the second locating device 22a comprises a filter and an amplifier, which are provided in order to filter out and amplify a received high-frequency locating signal. Furthermore, the signal processing device of the second locating device 22a generates a locating signal, which the locating antenna 24a of the second locating device 22a emits.

The computing unit determines from received locating signals locational information of an object of measurement 46a that is arranged in a workpiece and carries a low-frequency AC voltage. Furthermore, the computing unit determines locational information of further objects of measurement not shown any more specifically, reflecting the locating signal emitted by the locating antenna 24a of the second locating device 22a. Moreover, the computing unit is provided in order to determine whether the further objects of measurement carry the low-frequency AC voltage.

The shielding means 20a is formed as a metallic layer applied to an inner side of a support 52a of the hand tool device 10a. The shielding means 20a is formed as a tube extending perpendicularly to the front side 40a of the hand tool housing 42a. The shielding means 20a has an octagonal cross section on a plane that is aligned parallel to the front side 40a of the hand tool housing 42a. The individual areas 48a of the shielding means 20a are connected to one another in a conducting manner along abutting edges 50a of the areas 48a.

The four locating antennas 16a, 18a, 32a, 34a of the first locating device 12a are formed as metallic, electrically conducting layers applied to an outer side of the support 52a. The four locating antennas 16a, 18a, 32a, 34a are arranged offset in relation to the respectively adjacently arranged locating antenna 16a, 18a, 32a, 34a in each case by 90 degrees. Consequently, the shielding means 20a is respectively arranged between the locating antennas 16a, 18a, 32a, 34a. The locating antennas 16a, 18a, 32a, 34a of the first locating device 12a are arranged symmetrically in relation to the shielding means 20a.

The shielding means 20a completely encloses the locating antenna 24a of the second locating device 22a on planes that are aligned parallel to the front side 40a of the hand tool housing 42a. The locating antenna 24a of the second locating device 22a is provided in order to emit and receive a high-frequency locating signal. The hand tool device 10a comprises a grounding area 54a, which is arranged between the front side 40a of the hand tool housing 42a and the locating antenna 24a of the second locating device 22a. Furthermore, the grounding area 54a is arranged between the locating antennas 16a, 18a, 32a, 34a of the first locating device 12a and the front side 40a of the hand tool housing 42a. The grounding area 54a and the shielding means 20a are electrically separated from one another. Here there is a gap between the grounding area 54a and the shielding means 20a.

The locating antenna 24a of the second locating device 22a and the hand tool housing 42a have a functional opening 30a. Through the functional opening 30a, a functional means not shown any more specifically can be led perpendicularly to the front side 40a of the hand tool housing 42a through the hand tool 36a to the workpiece 14a. The locating antennas 16a, 18a, 32a, 34a of the first locating device 12a are arranged symmetrically in relation to the locating antenna 24a of the second locating device 22a and the functional opening 30a.

The locating antenna 24a of the second locating device 22a has a main locating direction 28a, which is aligned perpendicularly to the rear side 41a of the hand tool housing 42a. The locating antennas 16a, 18a, 32a, 34a of the first locating device 12a have main locating directions 56a, 58a, 60a, 62a, which are directed away from the shielding means 20a. Furthermore, the main locating directions 56a, 58a, 60a, 62a are directed away from the grounding area 54a. Consequently, the main locating directions 56a, 58a, 60a, 62a have in relation to the rear side 41a of the hand tool housing 42a an angle 64a of approximately 45 degrees. Other main locating directions that appear appropriate to a person skilled in the art are possible by means of different distances of the locating antennas 16a, 18a, 32a, 34a of the first locating device 12a from the shielding means 20a and/or from the grounding area 54a. Alternatively, the main locating directions of the locating antennas 16a, 18a, 32a, 34a of the first locating device 12a could be aligned parallel to the rear side 41a of the hand tool housing 42a. The locating antennas 16a, 18a, 32a, 34a of the first locating device 12a have main planes of extent that are aligned parallel to the main locating direction 28a of the locating antenna 24a of the second locating device 22a.

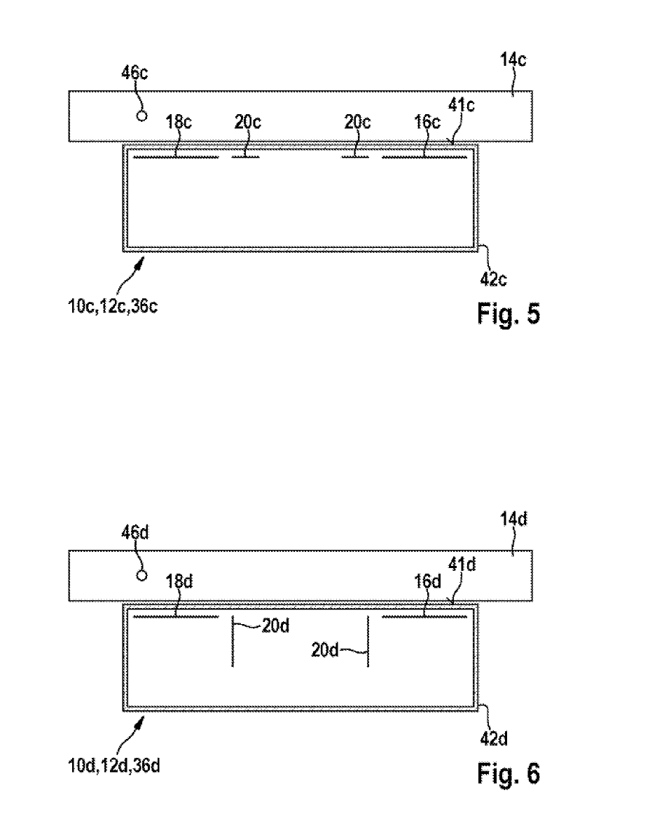

In FIGS. 4 and 6, three further exemplary embodiments of the invention are shown. The following descriptions and the drawings are restricted substantially to the differences between the exemplary embodiments, it being possible in principle also to refer to the drawings and/or the description of the other exemplary embodiments, in particular of FIGS. 1 to 3, with respect to components with the same designations, in particular with respect to components with the same reference numerals. To distinguish between the exemplary embodiments, the letter a has been added after the reference numerals of the exemplary embodiment in FIGS. 1 to 3. In the exemplary embodiments of FIGS. 4 to 6, the letter a has been substituted by the letters b to d.

FIG. 4 shows a hand tool 36b with a hand tool device 10b and a hand tool housing 42b. The hand tool device 10b comprises a locating device 12b and a shielding means 20b. The locating device 12b is provided in order to locate a low-frequency AC voltage of an object of measurement 46b in a workpiece 14b. The locating device 12b has a first locating antenna 16b and a second locating antenna 18b. The shielding means 20b is provided in order to shield a low-frequency locating signal. The shielding means 20b is arranged between the first locating antenna 16b and the second locating antenna 18b. The shielding means 20b is formed as a layer of which the main plane of extent is aligned parallel to a rear side 41b of the hand tool housing 42b. The locating antennas 16b, 18b of the locating device 12b are respectively formed as a layer of which the main plane of extent is respectively aligned perpendicularly to the rear side 41b of the hand tool housing 42b.

FIG. 5 shows a hand tool 36c with a hand tool device 10c and a hand tool housing 42c. The hand tool device 10c comprises a locating device 12c and a shielding means 20c. The locating device 12c is provided in order to locate a low-frequency AC voltage of an object of measurement 46c in a workpiece 14c. The locating device 12c has a first locating antenna 16c and a second locating antenna 18c. The shielding means 20c is provided in order to shield a low-frequency locating signal. The shielding means 20c is arranged between the first locating antenna 16c and the second locating antenna 18c. The shielding means 20c is formed as a layer of which the main extent is aligned parallel to a rear side 41c of the hand tool housing 42c. The locating antennas 16c, 18c of the locating device 12c are respectively formed as a layer of which the main plane of extent is respectively aligned parallel to the rear side 41c of the hand tool housing 42c.

FIG. 6 shows a hand tool 36d with a hand tool device 10d and a hand tool housing 42d. The hand tool device 10d comprises a locating device 12d and a shielding means 20d. The locating device 12d is provided in order to locate a low-frequency AC voltage of an object of measurement 46d in a workpiece 14d. The locating device 12d has a first locating antenna 16d and a second locating antenna 18d. The shielding means 20d is provided in order to shield a low-frequency locating signal. The shielding means 20d is arranged between the first locating antenna 16d and the second locating antenna 18d. The shielding means 20d is formed as a layer of which the main extent is aligned perpendicularly to a rear side 41d of the hand tool housing 42d. The locating antennas 16d, 18d of the locating device 12d are respectively formed as a layer of which the main plane of extent is respectively aligned parallel to the rear side 41d of the hand tool housing 42d.

1. A hand tool device comprising:
at least one locating device configured to locate a low-frequency alternating-current voltage in a workpiece, the at least one locating device having a first locating antenna and a second locating antenna; and
a shielding component configured to shield a low-frequency locating signal and arranged between the first locating antenna and the second locating antenna.

2. The hand tool device as claimed in claim 1, wherein the first locating antenna and the second locating antenna are arranged symmetrically in relation to the shielding component.

3. The hand tool device as claimed in claim 1, wherein at least one of the first locating antenna and the second locating antenna is formed by a conducting layer.

4. The hand tool device as claimed in claim 1, further comprising:
a second locating device having at least one locating antenna, the at least one locating antenna of the second locating device being substantially enclosed by the shielding component.

5. The hand tool device as claimed in claim 4, wherein the second locating device is configured to locate with a high-frequency locating signal.

6. The hand tool device at least as claimed in claim 4, wherein the first locating antenna of the at least one locating device and the second locating antenna of the at least one locating device are arranged symmetrically in relation to the at least one locating antenna of the second locating device.

7. The hand tool device as claimed in claim 4, wherein the first locating antenna of the at least one locating device and the second locating antenna of the at least one locating device have a main plane of extent that is aligned substantially parallel to a main locating direction of the at least one locating antenna of the second locating device.

8. The hand tool device as claimed in claim 1, further comprising:
a functional opening,
wherein the first locating antenna and the second locating antenna are arranged symmetrically in relation to the functional opening.

9. The hand tool device as claimed in claim 1, wherein:
the first locating device has a third locating antenna and a fourth locating antenna; and
the shielding component is arranged between the third locating antenna and the fourth locating antenna.

10. A hand tool having a hand tool device comprising:
at least one locating device configured to locate a low-frequency alternating-current voltage in a workpiece, the at least one locating device having a first locating antenna and a second locating antenna; and
a shielding component configured to shield a low-frequency locating signal and arranged between the first locating antenna and the second locating antenna.
